(19) United States
(12) Patent Application Publication
(10) Pub. No.: US 2016/0313412 A1
(43) Pub. Date: Oct. 27, 2016

(54) Anisotropic Magnetoresistance Sensor

(71) Applicant: Memsic Semiconductor (Wuxi) Co., Ltd., Wuxi (CN)

(72) Inventors: Dalai Li, Wuxi (CN); Zhengwei Huang, Wuxi (CN); Bin Li, Wuxi (CN); Leyue Jiang, Wuxi (CN)

(21) Appl. No.: 15/135,435

(22) Filed: Apr. 21, 2016

(30) Foreign Application Priority Data
Apr. 23, 2015 (CN) 201510198324.5

(51) Int. Cl. G01R 33/09; G01R 33/00; H01L 43/02; H01L 27/22; H01L 43/08; H01L 43/10

(52) U.S. Cl. CPC G01R 33/096; H01L 43/08; H01L 43/10; H01L 43/02; H01L 27/22; G01R 33/0023

(57) ABSTRACT

The present disclosure provides an anisotropic magnetoresistance (AMR) sensor. The AMR sensor comprises: a substrate layer; a buffer layer disposed on the substrate layer; a cap layer disposed on the buffer layer; and an intermediate layer disposed between the buffer layer and the cap layer and comprising a ferromagnetic layer and an antiferromagnetic layer. A magnetic moment of the ferromagnetic layer is oriented randomly after the ferromagnetic layer is interfered by an external large magnetic field. The magnetic moment of the ferromagnetic layer can be rearranged by an exchange bias between the antiferromagnetic layer and the ferromagnetic layer, such that the magnetic moment of the ferromagnetic layer is oriented uniformly after the ferromagnetic layer is interfered by a large magnetic field, thereby setting a direction of the magnetic moment of the ferromagnetic layer (SET function). A push-pull full bridge circuit based on the above anisotropic magnetoresistance sensor is also provided.

### CROSS REFERENCE TO RELATED PATENT APPLICATION

The present disclosure claims the priority benefit of Chinese Patent Application No. 201510198324.5, filed on 23 Apr. 2015, which is incorporated by reference in its entirety.

### TECHNICAL FIELD

The present disclosure relates to the field of sensors, and in particular, to an improved anisotropic magnetoresistance (AMR) sensor with a simple structure and low cost.

### BACKGROUND

With the development of the technology of magnetic field sensors, various types of magnetic field sensors are developed such as sensors based on Hall Effect and sensors based on magnetoresistance effect. A preparation of the Hall effect sensor may be combined with a traditional integrated circuit process, and thereby has advantages of low cost. However, there are also disadvantages of low sensitivity and large error. Additionally, another magnetic field sensor is developed based on AMR effect. A resistance of a magnetic film in the AMR sensor varies with an angle between a magnetization direction and a current direction, and such a phenomenon is called the AMR effect. The AMR sensor has characteristics of high sensitivity and low noise and is widely applied in various fields.

When interfered by an external large magnetic field, a magnetic moment of a ferromagnetic layer of the AMR sensor is oriented randomly, thereby affecting accuracy of output of the AMR sensor. To correct the output of the AMR sensor, a magnetic moment of the ferromagnetic layer needs to be magnetized again to rearrange and recover to an initial direction so as to realize the SET function. Generally, there are two methods for setting the magnetic moment in the ferromagnetic layer back into its initial direction. The first method is to deposit a metal stripe above or below a magnetoresistance stripe of the AMR sensor, apply a current in the metal stripe, and utilize a large magnetic field generated by the current to cause the arrangement of the magnetic moment of the ferromagnetic layer to be consistent, that is, to realize the SET function. The second method is to fix a permanent magnet near a magnetoresistance stripe during packaging of the sensor, and utilize a magnetic field generated by the permanent magnet to cause the arrangement of the magnetic moment of the ferromagnetic layer to be consistent so as to realize the SET function. The shortcomings of both methods lie in the fact that the preparation or packaging process is complicated and the cost is high.

Therefore, there is a need to provide an improved AMR sensor with a simple process and low cost.

### SUMMARY

This section is for the purpose of summarizing some aspects of the present disclosure and to briefly introduce some preferred embodiments. Simplifications or omissions in this section as well as in the abstract or the title of this description may be made to avoid obscuring the purpose of this section, the abstract and the title. Such simplifications or omissions are not intended to limit the scope of the present disclosure.

One object of the present disclosure is to provide an antiferromagnetically pinned anisotropic magnetoresistance (AMR) sensor which integrates a ferromagnetic layer and an antiferromagnetic layer on the same chip by a wafer-level process, so that a function of setting a direction of the magnetic moment of the ferromagnetic layer (herein referred to as the “SET function”) can be realized after being interfered by a large magnetic field by an exchange bias between the antiferromagnetic layer and the ferromagnetic layer.

According to one aspect of the present disclosure, the present disclosure provides an improved anisotropic magnetoresistance sensor. The AMR sensor comprises: a substrate layer; a buffer layer disposed on the substrate layer; a cap layer disposed on the buffer layer; and an intermediate layer disposed between the buffer layer and the cap layer and comprising a ferromagnetic layer and an antiferromagnetic layer. A magnetic moment of the ferromagnetic layer is capable of being rearranged by an exchange bias between the antiferromagnetic layer and the ferromagnetic layer.

According to another aspect of the present disclosure, the present disclosure provides a bridge circuit based on the improved anisotropic magnetoresistance sensor. The bridge circuit comprises: a first magnetoresistor, having a first terminal coupled to a bias voltage and a second terminal coupled to a first output terminal; a second magnetoresistor, having a first terminal coupled to the first output terminal and a second terminal coupled to a ground; a third magnetoresistor, having a first terminal coupled to the bias voltage and a second terminal coupled to a second output terminal; and a fourth magnetoresistor, having a first terminal coupled to the second output terminal and a second terminal coupled to the ground. A magnetic moment direction of the first magnetoresistor is antiparallel with a magnetic moment direction of the second magnetoresistor. A magnetic moment direction of the third magnetoresistor is antiparallel with a magnetic moment direction of the fourth magnetoresistor. The magnetic moment direction of the first magnetoresistor is antiparallel or parallel with the magnetic moment direction of the third magnetoresistor. Each magnetoresistor comprises: a substrate layer; a buffer layer disposed on the substrate layer; a cap layer disposed on the buffer layer; and an intermediate layer disposed between the buffer layer and the cap layer and comprising a ferromagnetic layer and an antiferromagnetic layer. A magnetic moment of the ferromagnetic layer is capable of being rearranged by an exchange bias between the antiferromagnetic layer and the ferromagnetic layer, i.e., the SET function is realized.

One of the features, benefits and advantages in the present disclosure is to provide techniques for integrating the ferromagnetic layer and the antiferromagnetic layer on one and the same chip by the wafer-level process, and realizing the SET function of the AMR sensor by an exchange bias between the ferromagnetic layer and the antiferromagnetic layer, after the AMR sensor is interfered by a large magnetic field, thereby lowering the process difficulty and reducing the cost.

Other objects, features, and advantages of the present disclosure will become apparent upon examining the following detailed description of an embodiment thereof, taken in conjunction with the attached drawings.

### BRIEF DESCRIPTION OF THE DRAWINGS

These and other features, aspects, and advantages of the present disclosure will become better understood with regard to the following description, appended claims, and accompanying drawings where:

FIG. 1 is a structure diagram showing a first embodiment of an antiferromagnetically pinned AMR sensor provided in the present disclosure;

FIG. 2 is a structure diagram showing a second embodiment of the antiferromagnetically pinned AMR sensor provided in the present disclosure;

FIG. 3 is a structure diagram showing a third embodiment of the antiferromagnetically pinned AMR sensor provided in the present disclosure;

FIG. 4 is a schematic diagram showing a first embodiment of a push-pull full bridge circuit based on the antiferromagnetically pinned AMR sensor provided in the present disclosure; and

FIG. 5 is a schematic diagram showing a second embodiment of the push-pull full bridge circuit based on the antiferromagnetically pinned AMR sensor provided in the present disclosure.

### DETAILED DESCRIPTION OF THE PREFERRED EMBODIMENTS

The detailed description of the present disclosure is presented largely in terms of procedures, steps, logic blocks, processing, or other symbolic representations that directly or indirectly resemble the operations of devices or systems contemplated in the present disclosure. These descriptions and representations are typically used by those skilled in the art to most effectively convey the substance of their work to others skilled in the art.

Reference herein to “one embodiment” or “an embodiment” means that a particular feature, structure, or characteristic described in connection with the embodiment can be included in at least one embodiment of the present disclosure. The appearances of the phrase “in one embodiment” in various places in the specification are not necessarily all referring to the same embodiment, nor are separate or alternative embodiments mutually exclusive of other embodiments. Further, the order of blocks in process flowcharts or diagrams or the use of sequence numbers representing one or more embodiments of the present disclosure do not inherently indicate any particular order nor imply any limitations in the present disclosure.

According to one aspect of the present disclosure, an improved antiferromagnetically pinned AMR sensor is provided. The AMR sensor comprises a substrate layer, a buffer layer disposed on the substrate layer, a cap layer disposed on the buffer layer; and an intermediate layer disposed between the buffer layer and the cap layer and comprising a ferromagnetic layer and an antiferromagnetic layer. A magnetic moment of the ferromagnetic layer is oriented randomly after the ferromagnetic layer is interfered by an external large magnetic field. In the present disclosure, the magnetic moment of the ferromagnetic layer can be rearranged by exchange bias between the antiferromagnetic layer and the ferromagnetic layer, such that the magnetic moment of the ferromagnetic layer is oriented uniformly after the ferromagnetic layer is interfered by the large magnetic field, thereby realizing a function of setting a direction of the magnetic moment of the ferromagnetic layer (SET function).

In one embodiment, the substrate layer is made from insulating or semiconductor material, which is preferably a Si substrate with a thermally oxidized surface. The buffer layer is made from conductive metal or alloy, which is preferably Ta or NiFeCr. The ferromagnetic layer is made from ferromagnetic material, which is preferably NiFe alloy. The antiferromagnetic layer is made from antiferromagnetic material, which is preferably one or more of IrMn, FeMn, PtMn and MnGa. The cap layer is made from conductive material, which is preferably Ta. A direction of the exchange bias is defined by applying an in situ magnetic field during deposition process or by annealing in a magnetic field.

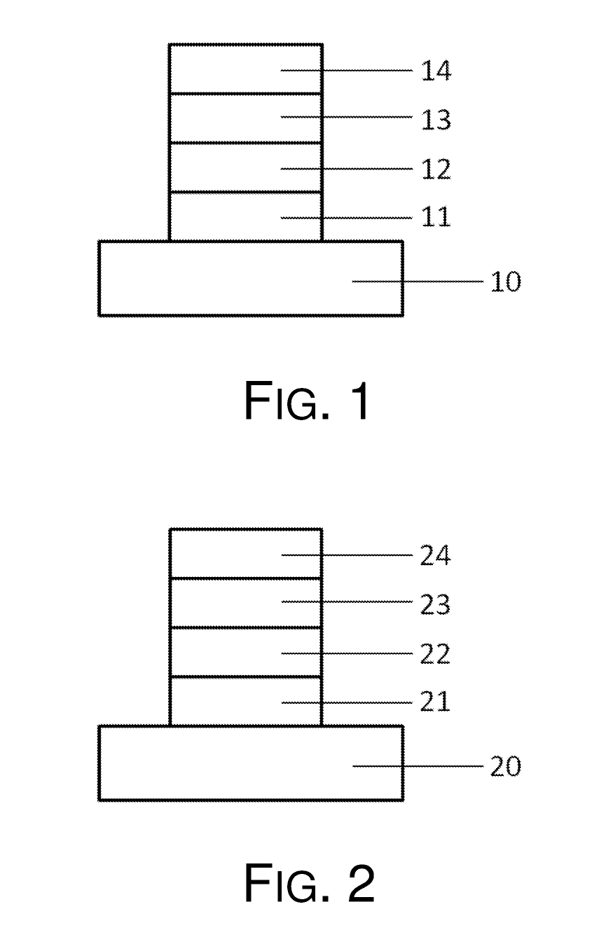

Referring to FIG. 1, which is a structure diagram showing a first embodiment of the antiferromagnetically pinned AMR sensor provided in the present disclosure, the top-pinned AMR sensor successively comprises a substrate layer 10, a buffer layer 11 deposited on the substrate layer 10, a ferromagnetic layer 12 deposited on the buffer layer 11, an antiferromagnetic layer 13 deposited on the ferromagnetic layer 12 and the cap layer 14 deposited on the antiferromagnetic layer 13.

Referring to FIG. 2, which is a structure diagram showing a second embodiment of the antiferromagnetically pinned AMR sensor provided in the present disclosure, the bottom-pinned AMR sensor successively comprises a substrate layer 20, a buffer layer 21 deposited on the substrate layer 20, an antiferromagnetic layer 22 deposited on the buffer layer 21, a ferromagnetic layer 23 deposited on the antiferromagnetic layer 22 and the cap layer 24 deposited on the ferromagnetic layer 23.

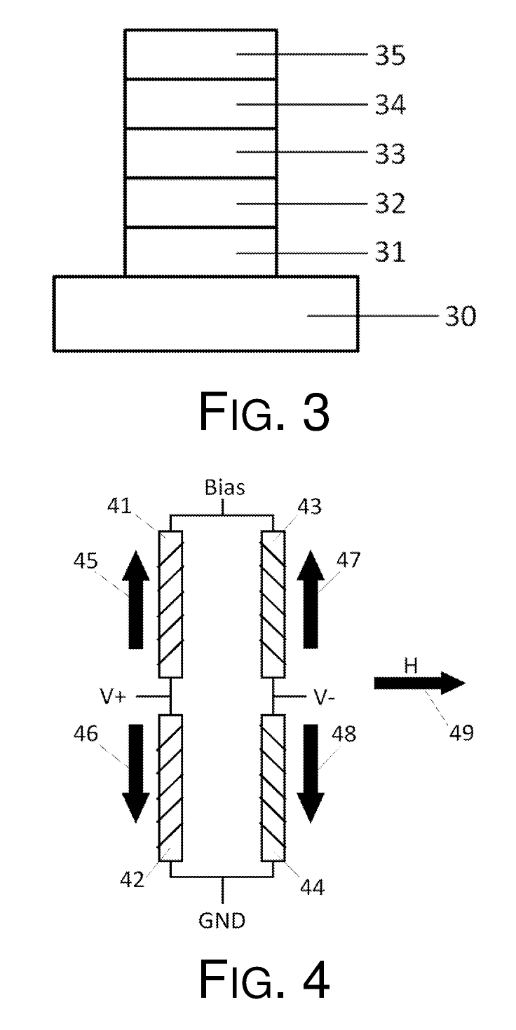

Referring to FIG. 3, which is a structure diagram showing a third embodiment of the antiferromagnetically pinned AMR sensor provided in the present disclosure, the sandwich-pinned AMR sensor successively comprises a substrate layer 30, a buffer layer 31 deposited on the substrate layer 30, a first antiferromagnetic layer 32 deposited on the buffer layer 31, a ferromagnetic layer 33 deposited on the first antiferromagnetic layer 32, a second antiferromagnetic layer 34 deposited on the ferromagnetic layer 33 and a cap layer 35 deposited on the second antiferromagnetic layer 34. In this embodiment, there are two antiferromagnetic layers 32 and 34, which sandwich the ferromagnetic layer 33.

It needs to be noted that the process for depositing respective layers on the substrate layer in the present disclosure is a traditional deposition process in the art and will not be described in detail here for simplicity.

Referring to FIG. 4, which is a schematic diagram showing a first embodiment of a push-pull full bridge circuit based on the antiferromagnetically pinned AMR sensor provided in the present disclosure, the push-pull full bridge circuit comprises a first magnetoresistor 41, a second magnetoresistor 42, a third magnetoresistor 43 and a fourth magnetoresistor 44. The first magnetoresistor 41 has a first terminal coupled to a bias voltage and a second terminal coupled to a first output terminal V+. The second magnetoresistor 42 has a first terminal coupled to the first output terminal V+ and a second terminal coupled to a ground. The third magnetoresistor 43 has a first terminal coupled to the bias voltage and a second terminal coupled to a second output terminal V−. The fourth magnetoresistor 44 has a first terminal coupled to the second output terminal V− and a second terminal coupled to the ground. Each magnetoresistor has the same structure with the antiferromagnetically pinned AMR sensor shown in FIG. 1, FIG. 2 or FIG. 3 so that each magnetoresistor can realize the SET function by exchange bias between the antiferromagnetic layer and the ferromagnetic layer.

A first direction 45 (which corresponds to a direction of arrow in the figure) of magnetic moment of the first magnetoresistor 41 is antiparallel with a second direction 46 (which corresponds to a direction of arrow in the figure) of magnetic moment of the second magnetoresistor 42. The first direction 45 of magnetic moment of the first magnetoresistor 41 is parallel with a third direction 47 (which corresponds to a direction of arrow in the figure) of magnetic moment of the third magnetoresistor 43. The third direction 47 of magnetic moment of the third magnetoresistor 43 is antiparallel with a fourth direction 48 (which corresponds to a direction of arrow in the figure) of magnetic moment of the fourth magnetoresistor 44.

Each magnetoresistor is integrated with barber poles, such that a current direction is at an angle of 45° with respect to a magnetic easy axis of the magnetoresistor. When the AMR sensor is placed in an external magnetic field H (the right arrow 49 in the figure), values of resistance of the first magnetoresistor 41 and the fourth magnetoresistor 44 decrease simultaneously, and values of resistance of the second magnetoresistor 42 and the third magnetoresistor 43 increase simultaneously, thereby realizing a differential output of the push-pull full bridge circuit via the first output terminal V+ and the second output terminal V−.

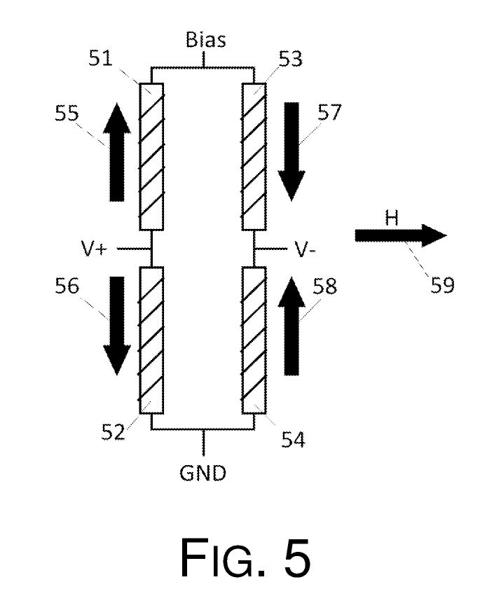

Referring to FIG. 5, which is a schematic diagram showing a second embodiment of the push-pull full bridge circuit based on the antiferromagnetically pinned AMR sensor provided in the present disclosure, the push-pull full bridge circuit comprises a first magnetoresistor 51, a second magnetoresistor 52, a third magnetoresistor 53 and a fourth magnetoresistor 54. Each magnetoresistor has the same structure with the antiferromagnetically pinned AMR sensor shown in FIG. 1, FIG. 2 or FIG. 3 so that each magnetoresistor can realize the SET function by exchange bias between the antiferromagnetic layer and the ferromagnetic layer.

A first direction 55 (which corresponds to a direction of arrow in the figure) of magnetic moment of the first magnetoresistor 51 is antiparallel with a second direction 56 (which corresponds to a direction of arrow in the figure) of magnetic moment of the second magnetoresistor 52. The first direction 55 of magnetic moment of the first magnetoresistor 51 is antiparallel with a third direction 57 (which corresponds to a direction of arrow in the figure) of magnetic moment of the third magnetoresistor 53. The third direction 57 of magnetic moment of the third magnetoresistor 53 is antiparallel with a fourth direction 58 (which corresponds to a direction of arrow in the figure) of magnetic moment of the fourth magnetoresistor 54.

Each magnetoresistor is integrated with barber poles, such that a current direction is at an angle of 45° with respect to a magnetic easy axis of the magnetoresistor. When the AMR sensor is placed in an external magnetic field H (the right arrow 59 in the figure), values of resistance of the first magnetoresistor 51 and the fourth magnetoresistor 54 decrease simultaneously, and values of resistance of the second magnetoresistor 52 and the third magnetoresistor 53 increase simultaneously, thereby realizing a differential output of the push-pull full bridge circuit via the first output terminal V+ and the second output terminal V−.

In the push-pull full bridge circuit of the present disclosure, the direction of magnetic moment of each of the magnetoresistors is pinned by corresponding antiferromagnetic layer via exchange bias. When the push-pull full bridge circuit is located in the external magnetic field along a sensitive direction of the magnetoresistor, the resistance of two adjacent bridge arms increases or decreases respectively, and the resistance of two opposite bridge arms increases or decreases simultaneously.

It needs to be noted that, in the present disclosure, the two designs of the push-pull full bridge circuits as shown in FIG. 4 and FIG. 5 are just examples, the specific sensor design is not limited to the two designs, and there may be a variety of layout schemes.

One of the features, benefits and advantages in the present disclosure is to provide techniques for integrating the ferromagnetic layer and the antiferromagnetic layer on one and same chip by a wafer-level process, and realizing a function of setting a direction of the magnetic moment of the ferromagnetic layer (SET function) of the AMR sensor by exchange bias between the ferromagnetic layer and the antiferromagnetic layer, after the AMR sensor is interfered by a large magnetic field, thereby lowering the process difficulty and reducing the cost.

The present disclosure has been described in sufficient details with a certain degree of particularity. It is understood to those skilled in the art that the present disclosure of embodiments has been made by way of examples only and that numerous changes in the arrangement and combination of parts may be resorted without departing from the spirit and scope of the present disclosure as claimed. Accordingly, the scope of the present disclosure is defined by the appended claims rather than the foregoing description of embodiments.

What is claimed is:

1. An anisotropic magnetoresistance sensor, comprising:
a substrate layer;
a buffer layer disposed on the substrate layer;
a cap layer disposed on the buffer layer; and
an intermediate layer disposed between the buffer layer and the cap layer and comprising a ferromagnetic layer and an antiferromagnetic layer with a magnetic moment of the ferromagnetic layer capable of being rearranged by an exchange bias between the antiferromagnetic layer and the ferromagnetic layer.

2. The anisotropic magnetoresistance sensor according to claim 1, wherein the ferromagnetic layer of the intermediate layer is disposed on the buffer layer, and wherein the antiferromagnetic layer of the intermediate layer is disposed on the ferromagnetic layer.

3. The anisotropic magnetoresistance sensor according to claim 1, wherein the antiferromagnetic layer of the intermediate layer is disposed on the buffer layer, and the ferromagnetic layer of the intermediate layer is disposed on the antiferromagnetic layer.

4. The anisotropic magnetoresistance sensor according to claim 1, wherein the antiferromagnetic layer comprises a first antiferromagnetic layer and a second antiferromagnetic layer with the first antiferromagnetic layer disposed between the ferromagnetic layer and the buffer layer and the second antiferromagnetic layer disposed between the ferromagnetic layer and the cap layer.

5. The anisotropic magnetoresistance sensor according to claim 1, wherein the substrate layer comprises an insulating material or a semiconductor material, wherein the buffer layer comprises a conductive metal material or an alloy material, wherein the ferromagnetic layer comprises a ferromagnetic material, wherein the antiferromagnetic layer comprises an antiferromagnetic material, and wherein the cap layer comprises a conductive material.

6. The anisotropic magnetoresistance sensor according to claim 5, wherein the substrate layer comprises a Si substrate with a thermally oxidized surface, wherein the conductive metal material or the alloy material comprises Ta or NiFeCr, and wherein the conductive material comprises Ta.

7. The anisotropic magnetoresistance sensor according to claim 5, wherein the ferromagnetic material comprises NiFe alloy.

8. The anisotropic magnetoresistance sensor according to claim 5, wherein the antiferromagnetic material comprises one or more of IrMn, FeMn, PtMn and MnGa.

9. The anisotropic magnetoresistance sensor according to claim 1, wherein a direction of the exchange bias is defined by applying an in situ magnetic field during deposition process or by annealing in a magnetic field.

10. A bridge circuit, comprising:
a first magnetoresistor, having a first terminal coupled to a bias voltage and a second terminal coupled to a first output terminal;
a second magnetoresistor, having a first terminal coupled to the first output terminal and a second terminal coupled to a ground;
a third magnetoresistor, having a first terminal coupled to the bias voltage and a second terminal coupled to a second output terminal; and
a fourth magnetoresistor, having a first terminal coupled to the second output terminal and a second terminal coupled to the ground;
wherein a magnetic moment direction of the first magnetoresistor is antiparallel with a magnetic moment direction of the second magnetoresistor, wherein a magnetic moment direction of the third magnetoresistor is antiparallel with a magnetic moment direction of the fourth magnetoresistor, and wherein the magnetic moment direction of the first magnetoresistor is antiparallel or parallel with the magnetic moment direction of the third magnetoresistor,
wherein each of the first, the second, the third and the fourth magnetoresistors respectively comprises:
a substrate layer;
a buffer layer disposed on the substrate layer;
a cap layer disposed on the substrate layer; and
an intermediate layer disposed between the buffer layer and the cap layer and comprising a ferromagnetic layer and an antiferromagnetic layer with a magnetic moment of the ferromagnetic layer capable of being rearranged by an exchange bias between the antiferromagnetic layer and the ferromagnetic layer.

11. The bridge circuit according to claim 10, wherein the ferromagnetic layer of the intermediate layer is disposed on the buffer layer, and wherein the antiferromagnetic layer of the intermediate layer is disposed on the ferromagnetic layer.

12. The bridge circuit according to claim 10, wherein the antiferromagnetic layer of the intermediate layer is disposed on the buffer layer, and wherein the ferromagnetic layer of the intermediate layer is disposed on the antiferromagnetic layer.

13. The bridge circuit according to claim 10, wherein the intermediate layer comprises a first antiferromagnetic layer and a second antiferromagnetic layer with the first antiferromagnetic layer disposed between the ferromagnetic layer and the buffer layer and the second antiferromagnetic layer disposed between the ferromagnetic layer and the cap layer.

14. The bridge circuit according to claim 10, wherein the substrate layer comprises an insulating material or a semiconductor material, wherein the buffer layer comprises a conductive metal material or an alloy material, wherein the ferromagnetic layer comprises a ferromagnetic material, wherein the antiferromagnetic layer comprises an antiferromagnetic material, and wherein the cap layer comprises a conductive material.

15. The bridge circuit according to claim 14, wherein the substrate layer comprises a Si substrate with a thermally oxidized surface, wherein the conductive metal material or the alloy material comprises Ta or NiFeCr, and wherein the conductive material comprises Ta.

16. The bridge circuit according to claim 14, wherein the ferromagnetic material comprises NiFe alloy.

17. The bridge circuit according to claim 14, wherein the antiferromagnetic material comprises one or more of IrMn, FeMn, PtMn and MnGa.

18. The bridge circuit according to claim 10, wherein a direction of the exchange bias is defined by applying an in situ magnetic field during deposition process or by annealing in a magnetic field.
